(19) United States
(12) Patent Application Publication
(10) Pub. No.: US 2005/0205988 A1
(43) Pub. Date: Sep. 22, 2005

(54) Die package with higher useable die contact pad area

(75) Inventor: Eric Michael Radza, Santa Clara, CA (US)

Correspondence Address: PILLSBURY WINTHROP SHAW PITTMAN LLP, 1650 TYSONS BOULEVARD, MCLEAN, VA, 22102, US

(73) Assignee: EPIC Technology Inc., Sunnyvale, CA (US)

(21) Appl. No.: 10/894,149

(22) Filed: Jul. 19, 2004

Related U.S. Application Data
(60) Provisional application No. 60/554,724, filed on Mar. 19, 2004.

(51) Int. Cl. H01L 23/12

(52) U.S. Cl. 257/704; 257/782

(57) ABSTRACT

A die package is provided including a circuit board with a recess for a die mounting area. A cap receiving area is located in the circuit board at least partially around the recess for the die mounting area. A cap located in the cap receiving area includes resilient contacts corresponding to at least some contact pad locations on one of a die or a secondary circuit board affixed to die to establish contact between the resilient contacts on the cap and the contact pad locations. A die for use with the die package can include contact pads in the heretofore unused center area of the die, as well as the typical peripheral contact pads, allowing more IO connections, more efficient connections and greater contact pad areas.

### CROSS REFERENCE TO RELATED APPLICATION(S)

This application claims the benefit of U.S. provisional application No. 60/554,724, filed Mar. 19, 2004, which is/are incorporated by reference as if fully set forth.

### BACKGROUND

Current IC production generally utilizes a die that is bonded to a carrier and a plurality of very fine wires, typically gold, to make the connections for signal input/output (IO), power and ground between pads located around the periphery of the die surface and the carrier leads. As more and more circuits are formed on a die, the pitches between the contact pads located around the edges of the die have become finer, resulting in higher inductance and resistance as the necks of the pads have been reduced in size. Additionally, the spacing between the gold wires becomes smaller so that there is the potential for unintentional contact and/or parallel inductance that result in a defective IC. It has also become increasingly difficult to provide more pads as well as to locate and connect the fine wires while still maintaining appropriate spacing.

### BRIEF DESCRIPTION OF THE DRAWING(S)

The foregoing Summary and the following detailed description will be better understood when read in conjunction with the following drawings, which illustrate preferred embodiments of the invention. In the drawings:

FIG. 1 is a side view, partially in cross section, of a first preferred embodiment of a die package in accordance with the present invention.

FIG. 2 is a side view, partially in cross-section, of a second preferred embodiment of a die package in accordance with the present invention.

FIG. 3 is a perspective view of a resilient contact sheet with a plurality of contacts formed in the desired locations prior to assembly and singulation to form the cap for the die package assemblies of FIGS. 1 and 2.

FIG. 4 is a perspective view showing the assembly of a cap for the die package assembly of FIGS. 1 and 2.

FIG. 5 is a plan view of a portion of the resilient contact sheet showing a number of different contact arrangements in accordance with the present invention.

FIG. 6 is a side view, partially in cross-section, of a third preferred embodiment of a die package in accordance with the present invention.

FIG. 7 is a side view, partially in cross-section, of a fourth preferred embodiment of a die package in accordance with the present invention.

FIG. 8 is a side view, partially in cross-section, of a fifth preferred embodiment of a die package in accordance with the present invention.

FIG. 9 is a side view, partially in cross-section, of a sixth preferred embodiment of a die package in accordance with the present invention.

FIG. 10 is a side view, partially in cross-section, of a seventh preferred embodiment of a die package in accordance with the present invention.

FIG. 11 is an enlarged view showing an alternate arrangement for the connection between the circuit boards in the die package of FIG. 10.

FIG. 12 is side view, partially in cross-section, of an eighth preferred embodiment of a die package in accordance with the present invention.

FIG. 13 a plan view of a resilient contact sheet configured for use as a ground or power plane as well as a heat spreader for the die package of FIG. 12.

FIG. 14 is a cross-sectional view of the contact sheet of FIG. 13.

FIG. 15 is a cross-sectional view of an alternate embodiment of a cap for a die package in the form of a two layer active heat sink.

FIG. 16 is a side view, partially in cross-section, of a preferred embodiment of an integrated multi-chip package in accordance with the present invention.

FIG. 17 is a perspective view showing the assembly of a cap structure for the integrated multi-chip package of FIG. 16.

### DETAILED DESCRIPTION OF THE PREFERRED EMBODIMENT(S)

Certain terminology is used in the following description for convenience only and is not limiting. The words “right,” “left,” “lower” and “upper” designate directions in the drawings to which reference is made. The words “inwardly”, “outwardly”, “upwardly” and downwardly” refer to directions toward and away from, respectively, the geometric center of the die package in accordance with the invention and designated parts thereof. The terminology includes the words above specifically mentioned, derivatives thereof and words of similar import.

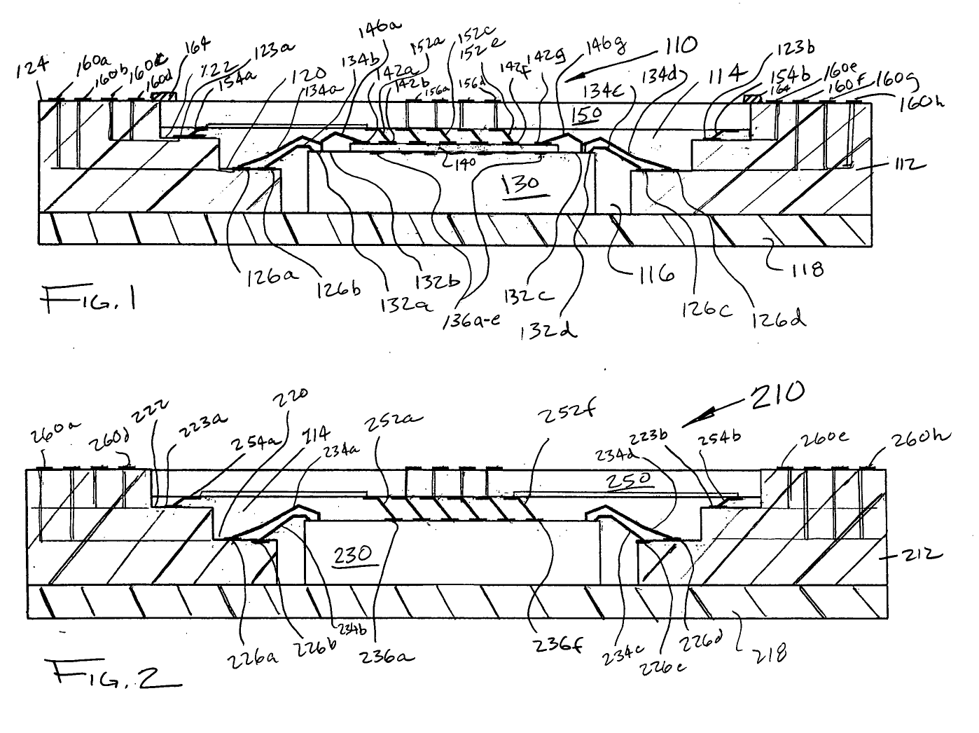

Shown in FIG. 1, is a first embodiment of a die package 110 in accordance with the present invention. The die package includes a circuit board 112 with a recess 114 for a die mounting area at 116. The circuit board 112 may be mounted on a principle substrate 118 or it can be formed as part of the circuit board 112, if desired. The circuit board 112 is made of known insulating or dielectric materials. The circuit board 112 can be formed as a multiple layer laminate printed circuit board or printed wiring board. As used herein, circuit board includes any inert substrate that carries circuits, either embedded within or on a surface thereof.

The recess 114 for the die mounting area 116 preferably includes at least two shoulders 120 and 122 that are recessed below an upper surface 124 of the circuit board 112. A plurality of contact pads is located on the first shoulder 120, with contact pads 126a-126d being represented. These contact pads 126a-126d are connected via wire bonds to contact pads 132a-d or a die 130 located in the die mounting area. The wire bonds 134a-d are of the type generally known in the art and may be of gold wire or any other suitable conductor and are preferably soldered, wedge bonded or ultrasonically bonded to the contact pads 126a-126d and 132a-132d in order to establish electrically connection between the die contact pad 132a-132d and the contact pads 126a-126d located on the surrounding circuit board substrate 112. These can be used to provide distribution of power and/or ground to the die 130 as well as for input and output (IO) signals to the die 130.

In accordance with the present invention, in addition to the peripheral contact pads 132a-132d on the die 130, the die 130 preferably includes a plurality of contact pads 136a-136e located in a central region of the die. In the first embodiment 110, a secondary circuit board 140 is flip chip bonded to an upper surface of the die in contact with the pads 136a-136e. The secondary circuit board 140 includes an insulative substrate with circuits extending on one or both surfaces thereof and/or therethrough in order to provide conductive paths from the lower surface of the secondary circuit board 140 and the upper surface of the die 130. Contact pads 142a-142g are preferably located on an upper surface of the secondary circuit board 140.

Still with reference to FIG. 1, the second shoulder 122 in the recess 114 preferably defines a cap receiving area in the circuit board 112 which is preferably located at least partially around the recess 114 of the die mounting area 116. A cap 150 is located in the cap receiving area defined by the shoulder 122 of the recess 114 and preferably includes resilient contacts 152 in a location corresponding to at least some of the contact pad locations 142a-142g of the secondary circuit board 140 affixed to the die 130 to establish contact between the resilient contacts 152 on the cap 150 and the contact pad locations. The contacts are preferably electrical contacts in the first embodiment of the die package 110 in accordance with the present invention. The cap 150 of the first embodiment of the invention is preferably a circuit board and can either be a printed circuit board or printed wiring board (commonly referred to as “circuit board” throughout) including a plurality of circuits at least on the lower surface thereof and/or extending therethrough to circuits located on the upper surface.

The cap 150 preferably includes a first group of the resilient contacts 152a-152e located in complementarily positions to contact pad locations 142b-142f on the secondary circuit board 140 mounted on the die 130, and further includes a second group of contacts 154a, 154b located in the complementary positions to contacts 123a, 123b on the circuit board 112 positioned on the shoulder 122. The circuit board contacts 123a, 123b are preferably positioned at least partially around the recess 114. With respect to all of the contact pads and resilient contacts noted above, those skilled in the art will recognize that only a limited number of the contact pads and resilient contacts have been shown and identified for convenience in the drawings. However, the number of contact pads and resilient contacts can be varied depending upon the particular application. Additionally, wire bonds 146a, 146b may extend directly from the die 130 to contact pads 142a and 142g on the secondary circuit board 140.

In accordance with the first preferred embodiment of the die package 110, electrical contacts can therefore be routed from a center area of the die 130 via the secondary circuit board 140 and the resilient contacts 152a-152e located on the cap 150 through circuits on the cap 150 to resilient contacts 154a, 154b on the periphery of the cap 150 which engage contact pads 123a, 123b located in the cap receiving area defined by the shoulder 122. Alternatively, conductive paste or solder could be used in place of the contacts 154a, 154b. This is in addition to the standard wire bonds 134a-134d which can be connected to the peripheral contact pads 132a-132d typically located on the upper surface of the die 130.

In accordance with the invention, this provides additional locations for contact pads on the surface of the die 130 without the need for more closely spaced wire bonds around the die periphery which can create problems with respect to signal passage and inductance resulting in faulty performance of the IC due to poor signal quality. The pads 126a-126d and 123a, 123b located on the circuit board 112 are connected to further circuits, partially illustrated, in order to route power and signals into and out of the die 130 as well as to provide grounds as required. This provides a solution for a low cost die packaging in which low inductance and low resistance is possible for the circuits connected into and out of the die 130 as well as higher reliability based on the use of a cap 150 including resilient contacts and circuits thereon. Power and/or IO signals into and out of the die package 110 can be provided by further contacts 160a-160h located on the upper surface of the circuit board 112 or the lower surface thereof.

The cap 150 is preferably secured in position utilizing a clamp or holding mechanism, partially represented as 164, which places downward pressure at least around a periphery of the cap and/or pressure in a distributed manner over the surface of the cap 150. The cap 150 may also include additional contact pads 156a-d on an upper surface thereof. This arrangement provides many solutions for the distribution of signals, power and ground potentials to the die 130 which allows the contact pads on the periphery of the die to be widened and shortened for better IO signal transmission, and also provides a new typically unused area on the surface of the die 130 for making connections.

The cap 150 may also be used as a ground plane or a heat sink as described in further detail below. While the cap 150 is preferably removably mounted in the cap receiving area formed in the circuit board 112, it can also be fixed in place using an adhesive, by fusing and/or by any other suitable bonding or mechanical means.

Shown in FIG. 2, is a second embodiment of a die package 210 in accordance with the present invention. The die package 210 is similar to the die package 110 as noted above and like elements have been identified by similar element numbers. In this second embodiment of the die package 210, the secondary circuit board 140 as noted above in connection with the first embodiment has been eliminated and the resilient contacts 252a-252f on the cap 250 are located in complementary positions to the contact pads 236a-236f on the die 230. The cap 250 preferably also includes the resilient contacts 254a, 254b around at least a portion of a periphery thereof that engage contact pads 223a, 223b on the shoulder 222 in the circuit board 212. The circuit board 212 is similar to the circuit board 112 described above and a substrate 218 is preferably also provided upon which the circuit board 212 and die 230 are mounted. The substrate can be combined with the circuit board 212, if desired. The circuit board 212 preferably also includes a recess 214, similar to the recess 114 described above, as well as the first shoulder 220, with the shoulder height in the recess 214 being adjusted to compensate for any adjustment in the height of the die 230 and the position of the cap 250. Additionally, the lengths of the resilient contacts 252a-252f can also be adjusted, as necessary. Wire bonds 234a-234d are preferably also used to connect the contact pads 232a-232d on the die 230 to contact pads 226a-226d on the first shoulder 220 of the circuit board 220. Representative contacts 260a-260h are shown on the upper surface of the circuit board 212 along with representative circuits being shown extending through the circuit board 212, which can be of a laminated construction. Additionally, representative circuits are shown extending along the lower surface and through the substrate of the cap 250. Those skilled in the art will recognize from the present disclosure that the circuits are merely representative and the circuits can be formed via lithographic techniques, such as by masking a conductive substrate and etching the substrate so that the circuits remain on the upper and/or lower surfaces of the circuit board, as well as through the use of conductive plating or conductive material extending therethrough in order to make electrical circuits which extend through the insulative substrate. This is also true with respect to the circuit board 212 and the circuits extending through all or a part thereof.

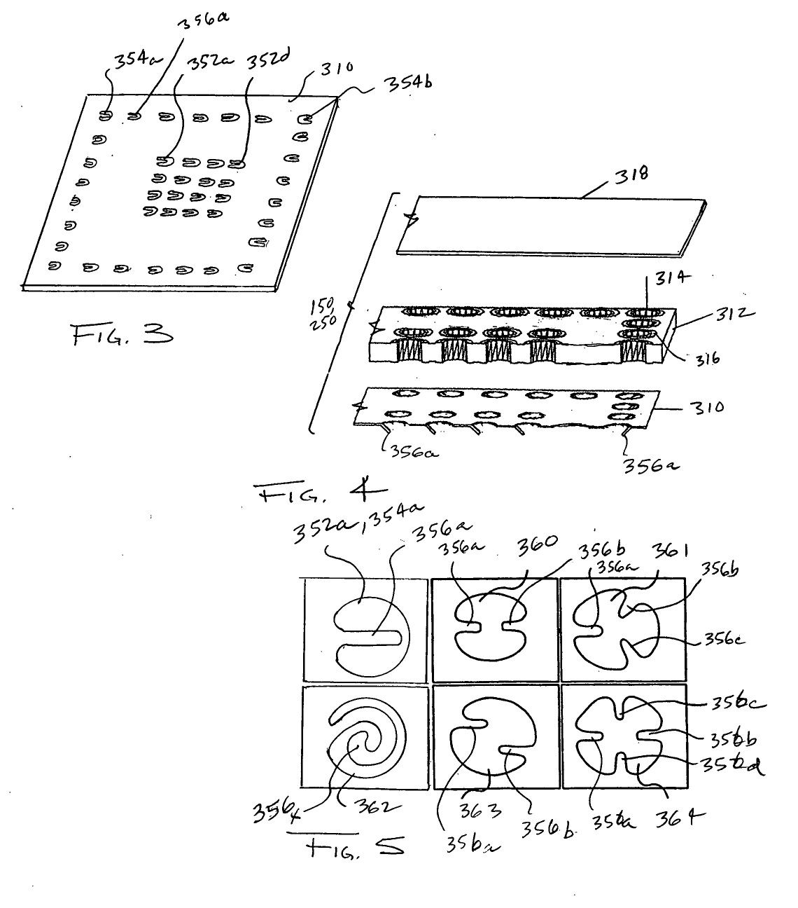

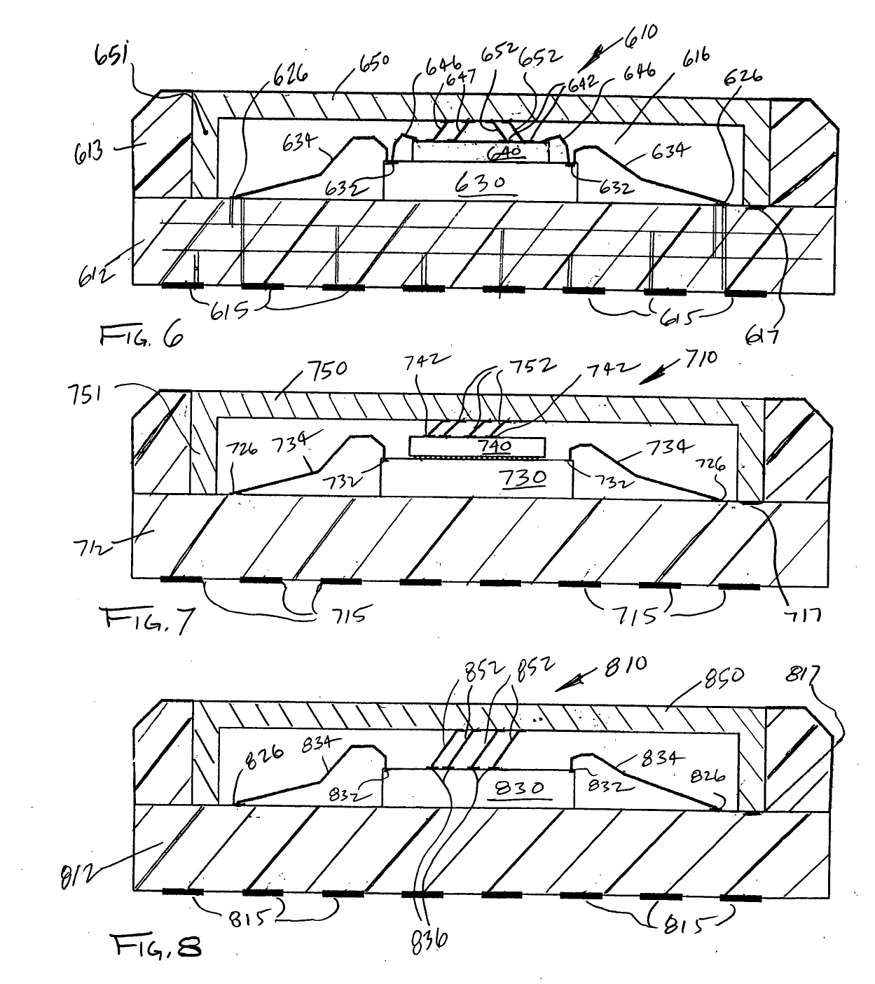

Referring to FIGS. 3-5, the construction on the caps 150, 250 in accordance with the present invention is described in further detail. Referring to FIG. 3, a resilient, conductive material sheet 310 is shown with a plurality of contacts 354a, 354b and 352a-352d located thereon. The resilient contacts 352, 354 each include at least one resilient arm 356a or may include a plurality of resilient arms 356a-356d illustrated in the several different types of contacts 352a, 354a, 360, 361, 362, 363 and 364 shown in FIG. 5a. The sheet 310 is preferably patterned to form an array of contact elements in the desired locations each or which includes a base portion and one or more elastic portions 356a-356d. Various different contact forms can be utilized on the same sheet, if desired, depending upon the particular application. The spring portions 356a-d are preferably formed by etching, stamping or other means. The resilient portions 356 are then bent or formed outwardly from the sheet in order to provide an outwardly extending resilient contact arm that forms the active portion of the contact. The sheet is preferably formed of copper (Cu) or beryllium copper (BeCu). Alternatively, brass, phosphorous bronze or other suitable alloys may also be used.

Once the resilient contacts have been formed in an array in the sheet of resilient, conductive material 310, the sheet 310 is bonded to a dielectric substrate 312 prior to singulation of at least some of the contacts 352a-352d, 354a and 354b from one other. This singulation is preferably carried out in a mask and etch process as described in detail in the assignee's co-pending U.S. Patent Application 60/547,912, filed Feb. 26, 2004, which is incorporated herein by reference as fully set forth. The insulative substrate 312 can include through plated vias 314, 316 at various locations in order to provide electrical continuity through the substrate. Additionally, circuit traces can be formed during the singulation process such that some of the resilient contacts 352a-352d are electrically connected to some of the resilient contacts 354a, 354b via conductive circuit traces remaining on the lower surface of the insullative substrate 312. An upper sheet of conductive material 318 can be bonded to an upper surface of the insullative substrate 312. This upper sheet 318 can be patterned and etched using lithographic techniques in order to form contact pads and circuit traces on the upper surface of the caps 150, 250, if desired. Alternatively, depending upon the particular application, there may be no need to provide a conductive sheet 318 on the cap 150, 250. Additionally, it is further possible to provide a second conductive, resilient sheet which has been patterned and formed in order to provide resilient contact arms which extend upwardly from the sheet 318 in order to provide resilient contacts on the upper surface of the cap 150, 250 which can then be singulated, as required.

The electrical continuity is established between the vias 314, 316 and the resilient contacts 352a-d, 354a-b via over plating the caps 150, 250 with gold or any other suitable conductive material which provides electrical continuity as well as superior corrosion resistant. While several preferred contact configurations 352a, 354a, 260, 261, 362, 263, 364 have been shown in FIG. 5 in flat form, it is understood that the resilient contact arms 356a-d and 356x of the contacts would be displaced outwardly from the plane of the sheet material in which they are formed and can either extend linearly or be formed in a curved manner, such as over a curved forming surface, in order to provide a contact with a desired length, contact area and resiliency. Additionally, the composition of the resilient conductive sheet 310 can be varied to provide particular electrical properties, as desired. Of note, the resilient contact arm 356x shown in FIG. 5 provides an extended range contact through the wound configuration provided.

While the preferred contacts for the cap 150, 250 have been described, those skilled in the art will recognize that other types of resilient contacts can be utilized within the scope and spirit of the present invention, and the invention is not limited to the particular type of resilient contacts disclosed herein. For example, resilient contacts that are individually connected to the insulative sheet 312 could be provided as well as spring-type contacts that extend into pockets formed in the insulative sheet 312 or other suitable resilient contact types.

Shown in FIG. 6, is a third embodiment of a die package 610 in accordance with the present invention. The die package 610 includes a circuit board 612 having a plurality of circuits extending therein and/or therethrough. A plurality of contact pads 626 are located on the circuit board 612 and are preferably connected to contact pads 632 on a die 630. The die 630 is preferably mounted on an upper surface of the circuit board 612 and wire bonds 646 extend between the contact pads 632 on the die and the contact pads 636 on the upper surface of the circuit board 612. A secondary circuit board 640 is connected to the upper surface of the die 630, preferably by flip chip bonding. The secondary circuit board 640 can also be connected to contact pads located on the surface of the die 630 by a wire bond 646. Embedded circuits may be located within the secondary circuit board 640 to make connections with additional contact pads 636 located on the upper surface of the die 630. A cap 650 made of a metal material is mounted over the die. The cap 650 includes resilient connectors 652 in the form of resilient leaf springs mounted thereto located in positions that correspond to the locations of contact pads 646 on the upper surface of the secondary circuit board 640. This allows the cap 650 to be used for current conduction or as a ground plane. Alternatively, as is also shown in FIG. 6, resilient contact arms 647 can extend upwardly from the upper surface of the secondary circuit board 640 and contact the metal cap 650. The resilient contact arms 647 are preferably formed in the same manner as the contact arms 356 as described above. The resilient connectors 652 may be made in any manner, such as punching stamping and/or etching, and may be connected singly or in an array to the metal cap 650 by bonding, welding, soldering, fusion or ultrasonic welding or any other suitable methods.

The cap 650 is preferably held laterally in position via walls 613 extending upwardly from the circuit board 612 around the die mounting area 616, effectively creating a cap receiving area. The walls 613 can be preformed on the printed circuit board and the cap 650 can be bonded, clamped or connected in place, or the walls 613 may take the form of encapsulating material formed around and/or over the cap 650 once it has been properly positioned.

The cap 650 preferably includes legs 651 that are connected to at least one contact pad 617 on the circuit board 612. Contact pads 615 are also located on the lower surface of the circuit board 612 and are connected to circuits located within or on the circuit board 612 in order to provide power, ground and/or I/O connections to and from the die 630.

While the third embodiment of the die package 610 is useful for die packages with perimeter contact pads for connection to the package, it is also possible to provide a greater number of contact pads on the die in a previously unused central area in accordance with the fourth embodiment of the invention, as shown in FIG. 7, in which the secondary circuit board 740 is flip chip bonded to the die 730. The metal cap 750 includes the resilient contacts 752 that engage contact pads 742 on the secondary circuit board 740 in order to provide a power plane, grounding plane and/or electrical shielding. The cap 750 is held in position on the circuit board 712 in the same matter as the cap 650, as noted above. Preferably, the cap 750 also includes at least one leg 751 which is connected directly to the circuit board 712 by any conventional method, such as solder, conductive epoxy or pressure contact with a pad 717 located on the upper surface of the circuit board 712. Contact pads 715 are preferably provided on the lower surface of the circuit board 712 for connection with other electrical or electronic assemblies through known means, such as solder or resilient contacts. The perimeter contact 732 on the die 730 is connected to contact 726 on the circuit board 712 using wire bonds or other connectors in the known matter.

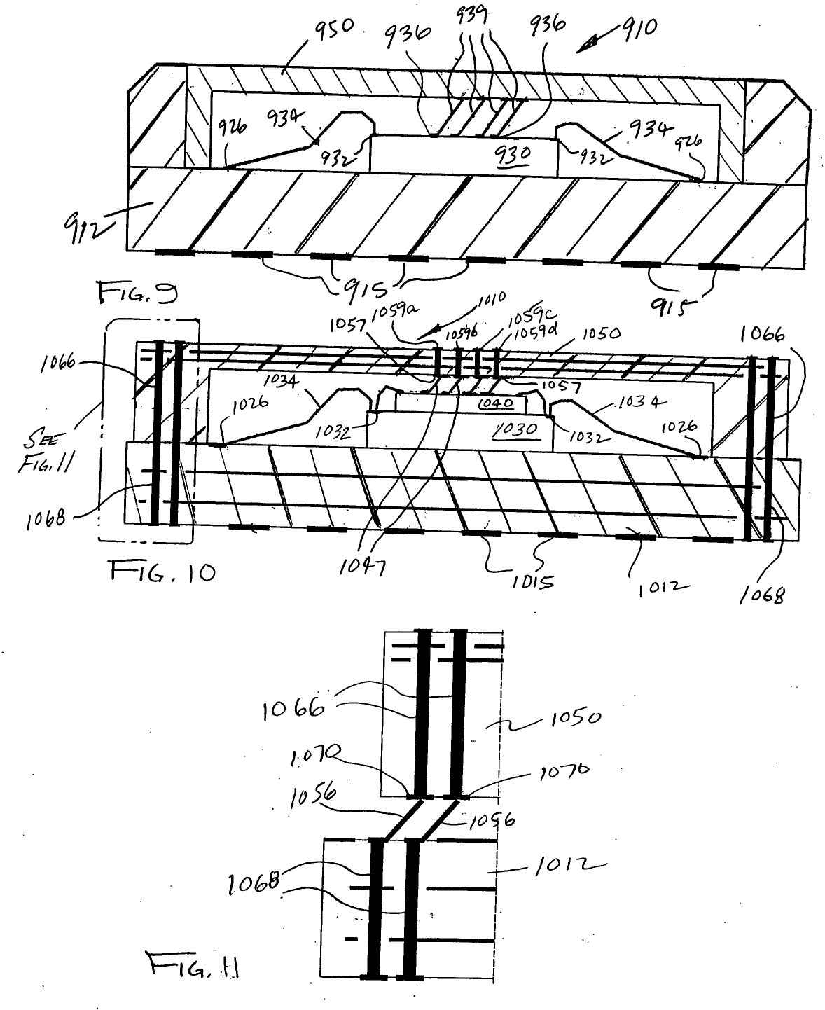

Referring now to FIG. 8, a fifth embodiment of the die package 810 is shown which is similar to the third preferred embodiment of the die package 610 shown above in FIG. 6. The die package 810 includes a circuit board 812 with power, ground and date I/O connections 815 located on a lower surface thereof. These are connected via circuits located within and/or on the circuit board 812 to contact pads 826 on an upper surface thereof which are connected by wire bonds 834 to perimeter pads 832 of a die 830. The metal cap 850 which provides a ground or power plane is connected via resilient contact arms 852 to contact pad 836 located directly on the die 830. This eliminates the need for a secondary circuit board while providing a die package 810 which can provide shielding at low cost and in a small area package. The resilient contact arms 852 may be spring contacts formed with a resilient spring material and may be formed in an array prior to connection to the metal cap 850 or may be formed individually and attached via any known means such as conductive adhesive, solder, ultrasonic welding or any other suitable attachment method.

Referring now to FIG. 9, a sixth embodiment of a die package 910 in accordance with the present invention is shown. The sixth embodiment of the die package 910 is similar to the fifth embodiment of the die package 810 and includes the circuit board 912 with contact pads 915 on a lower surface thereof. The die 930 is bonded to an upper surface of the circuit board 912, with perimeter contact pads 932 of the die 930 being connected to contact pads 926 on an upper surface of the circuit board 912 via wire bonds 934. The cap 950 is made of a metal material and resilient contacts 939 are attached to and extend upwardly from pads 936 on a surface of the die. The resilient contact arms 939 are connected to the pad locations on the upper surface of the die via ultrasonic welding, conductive adhesive bonding or any other suitable attachment method. The resilient contact arm 939 provide connections to the cap 950, which in the present embodiment acts as a heat sink and/or a ground plane while providing shielding to the die 930.

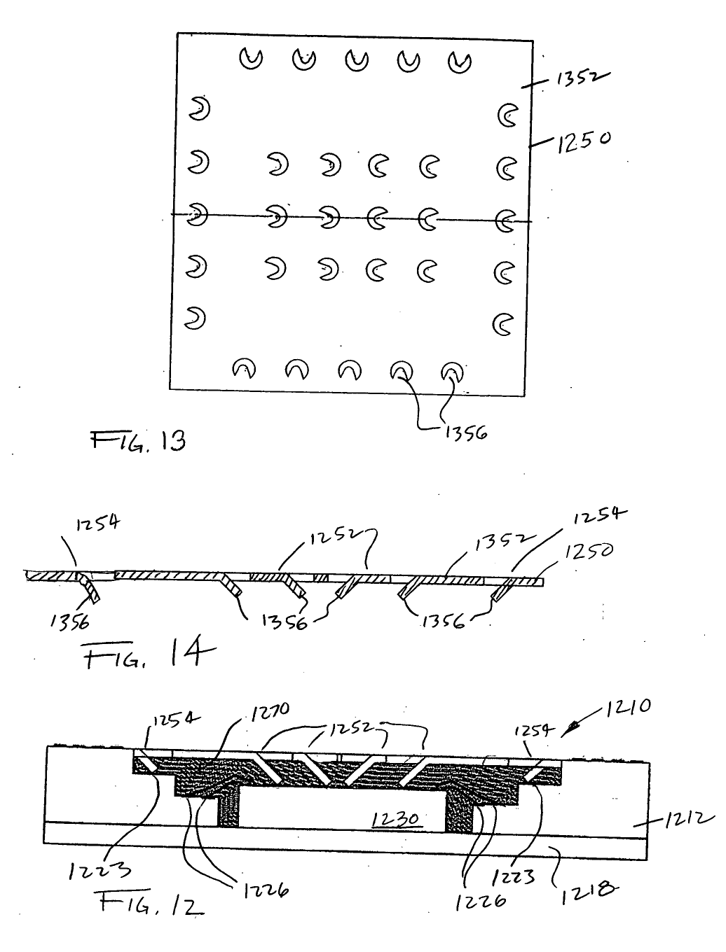

Referring now to FIG. 10, a seventh embodiment of a die package 1010 is shown. The die package 1010 of the seventh preferred embodiment of the invention is similar to the die package 710 except the cap 1050 comprises a circuit board having a plurality of circuits located on a surface thereof or between the layers of a multi-layer substrate from which the cap 1050 is formed. Connections 1059a-1059d, in the form of pads and conductive vias are electrically connected to circuits within or on the substrate forming the cap 1050 as well as to contact pads 1057 located on an inner surface of the cap 1050. Resilient contact arms 1047 extend up from the secondary circuit board 1040 in the same manner at the resilient contact arm 647 as described above. The secondary circuit board 1040 is connected to perimeter pads 1032 on the die 1030 via wire bonding. Additionally, wire bonds 1034 are used to connect other of the perimeter pads 1032 on the die 1030 to contact pads 1026 on the upper surface of the circuit board 1012. Vias 1066 are connected with circuits on or within the substrate forming the cap 1050 and extend to a lower surface of the cap 1050 in a support region thereof which maintains the center region of the cap 1050 above the secondary circuit board 1040 at a pre-determined height. These via 1066 can be connected to vias 1068 located in the circuit board 1012 in order to provide further electrical connections to circuits located on, within or in substrates of the circuit board 1012. These vias 1066, 1068 can be used to provide I/O signals, power and grounds from the circuit board 1012 through the cap 1050 and to the die 1030. The cap 1050 is held in location via removable clamps or a mechanical holding assembly so that it can be removed for inspection and/or replacement of the die 1030, as required. Alternatively, it can be attached with solder, conductive adhesive or other known attachment methods.

Referring to FIG. 11, the vias 1066 in the cap 1050 and the vias 1068 in the circuit board 1012 are shown in detail. Internal connections to circuits and/or conducting planes within the cap 1050 and the circuit board 1012 are shown. In addition, resilient contact arms 1056, formed in the same manner as the resilient contact arms 356 noted above, are connected to contacts located on the upper surface of the circuit board 1012 in order to place the contact pads 1070 located on the lower surface of the cap in electrical communication with the vias 1066. Alternatively, the resilient contact arms 1056 could be connected to the lower surface of the cap 1050 and extend down and connect to contact pads located on the upper surface of the circuit board 1012. While resilient contact arms 1056 are preferred, those skilled in the art will recognize that other types of resilient connectors can be utilized in order to provide a removable connection with high contact for liability.

Referring to FIG. 12, a die package 1210 is shown in which the die 1230 is mounted on a circuit board 1212. The circuit board 1212 can be mounted on a substrate or circuit board 1218, or the base portion 1218 may be formed as part of the circuit board 1212. Perimeter pads of the die 1230 are connected to contact pads 1226 located on the circuit board 1212. Ground and/or power are provided from the circuit board 1212 to the die 1230 via the cap 1250. Contacts 1252 on the cap 1250 contact power or ground contact pads on the die 1230, and contacts 1254 on the cap 1250 contact pads 1223 on the circuit board 1212. This provides a simple ground or power plane that can also act as a heat sink. The die 1230 and the cap 1250 are bonded or held in place using a liquid injection molding material 1270. This provides an inexpensive die package arrangement 1210 with high reliability and an active heat sink.

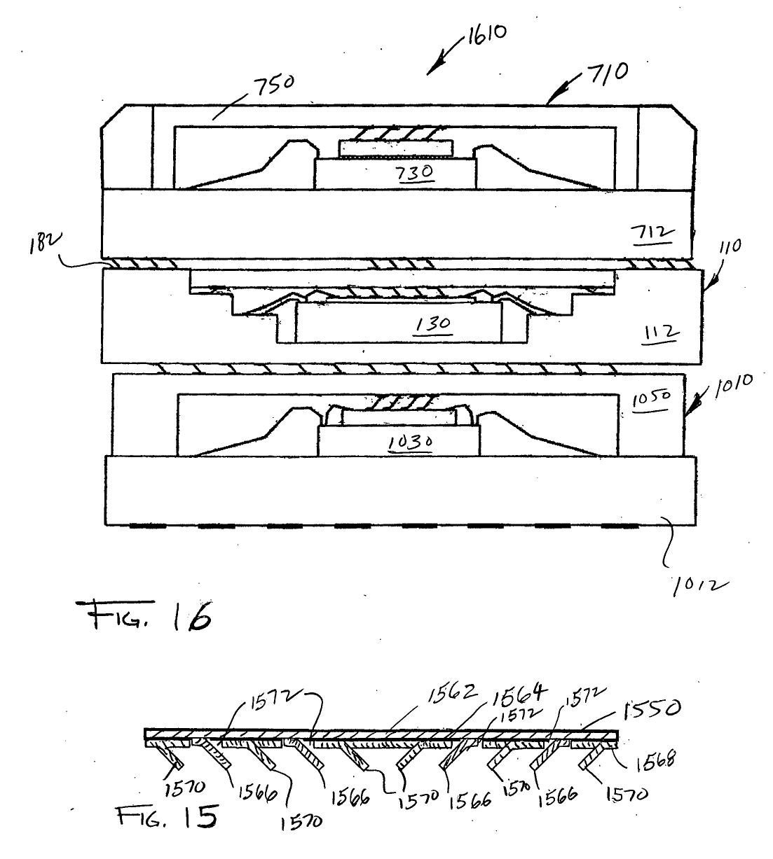

Referring to FIGS. 13 and 14, the cap 1250 for use in the die package 1210 in accordance with the present invention is shown. The cap 1250 is formed from a resilient metallic sheet 1352 having a plurality of resilient contact arms 1356 defined therein. The contact arms 1356 are formed through a lithographic mask and etch process in which the resilient contact arms 1356 are formed, which were then bent outwardly from the sheet, shown in detail in FIG. 14, in order to form the resilient contact arms 1356. The contacts are gold plated. While a lithographic mask and etch process is preferably, the contacts 1356 can be formed through a stamping or other process.

Referring now to FIG. 15, a cap 1550 in the form of a two layer active heat sink is shown. A base heat sink 1562 is oxidized or coated with a dielectric material 1564, leaving specific open areas to the base metal 1562. Contacts 1566 are attached to the uncovered areas to provide a path from a die to a heat sink. A single layer of conductive material 1568 having a plurality of resilient contact arms 1570 similar to the contact arms 356 and 1356 described above can be bonded on the lower surface of the heat sink 1562. Clearance openings 1572 are provided in the areas of the contacts 1566 so that the contacts 1570 are isolated from the contacts 1566 in order to provide a separate and/or additional heat sink from a ground or power plane.

Shown in FIG. 16, is an integrated multi-chip die package 1610 in accordance with the present invention. The integrated multi-chip package includes a first die package 110, as described above with a die mounting area 116 and a cap receiving area defined by the shoulder 122, as described above. The cap 150 is located in the cap receiving area and includes resilient contacts 152a-f and 154a-b located on a lower surface thereof corresponding to at least some contact pad locations on one of the die or a secondary circuit board affixed to the die 130. At least one of pads or resilient contacts 182 is located on an upper surface of the first cap 150. A second die package 710 as described above is located above the first die package 110 and includes the other of pads or spring contact 715 located in complementary positions to the pads or resilient contacts on the cap 150 of the first die package 110. Circuits (not shown in detail) extend through the circuit boards 112, 712 in order to form an integrated multi-chip package that is easily assembled, compact and expandable. For example, a third die package, such as the die package 1010 as described above, can be located under the first die package 110. The contacts 1059a-d as well as additional contacts on the cap 1050 are located in complementary positions to resilient contacts on the bottom of the circuit board 112 of the first die package 110 in order to make an expanded integrated multi-chip package. The multi-chip die packages in accordance with the present invention are expandable and scalable to meet the requirements of any given application, and have a compact arrangement to allow use in many applications where footprints on pc boards or envelopes for chip mounting arrangements within a given product housing are limited. While one specific arrangement is illustrated, those skilled in the art will recognize from the present disclosure that other arrangements having two or more die packages connected together in order to provide electrical contacts between the two die packages in the stacked arrangement could be utilized.

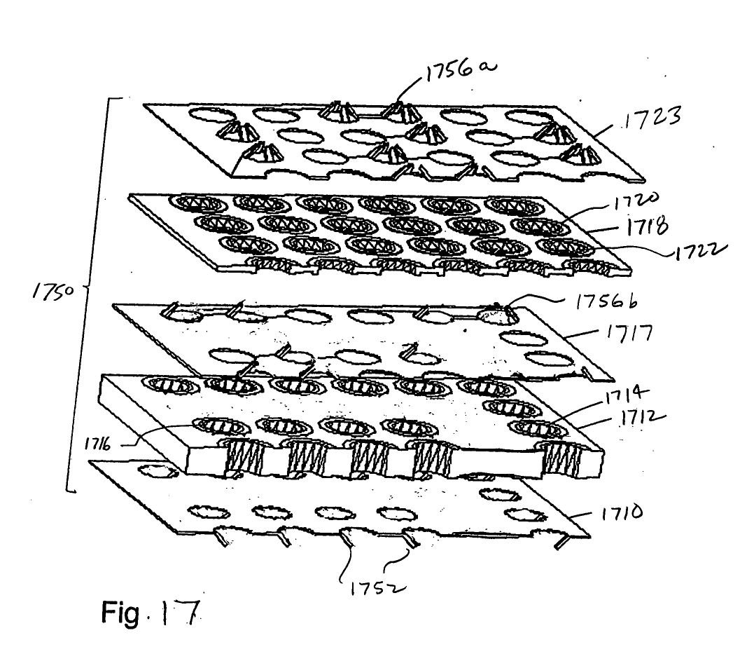

Shown in FIG. 17, is the assembly of a cap 1750 in accordance with the present invention that has resilient contacts 1752 that extend downwardly into contact with a die or a secondary circuit board mounted on a die for electrical connection and/or thermal energy transfer, as well as resilient contacts 1756a, 1756b that extend upwardly for contacting another electronic component or another die package in accordance with the invention. The cap 1750 includes a first sheet of resilient conductive material 1710 that is masked and etched in order to form the contact arms of the resilient contacts 1752, which are then bent outwardly from the sheet 1710. The sheet 1710 is bonded to an insulative substrate 1712, which includes a plurality of through plated vias 1714, 1716 located at various locations corresponding to at least some of the resilient contacts 1752, prior to at least some of the contacts 1752 being singulated from one another, preferably through masking and etching. A second sheet of resilient conductive material 1717 that is masked and etched in order to form the contact arms of the resilient contacts 1756b, which are then bent outwardly from the sheet 1717, is bonded to an upper surface of the substrate 1712. The second sheet 1717 includes at least some clearance holes around the vias 1714 and/or 1716 so that they do not contact the second sheet. A second insulative substrate 1718 is located over the second conducive sheet 1717, and includes at least some through-plated vias 1720, 1722 located in positions corresponding to at least some of the vias 1714, 1716 in the first insulative substrate 1712. A third sheet of resilient conductive material 1723 that is masked and etched in order to form the contact arms of the resilient contacts 1756a, which are then bent outwardly from the sheet 1710, is then located on top of the second insulative substrate 1718, prior to at least some of the contacts 1756a being singulated from one another by masking and etching. The cap assembly 1750 is preferably plated with a conductive material, such as gold, in order to establish electrical continuity between the contacts and the vias, in order to provide a plurality of different electrical paths through the cap 1750.

Although the present invention has been described in detail, it is to be understood that the invention is not limited thereto, and that various changes can be made therein without departing from the spirit and scope of the invention, which is defined by the attached claims.

1. A die package, comprising:
a circuit board with a die mounting area;
a cap receiving area on the circuit board located above and at least partially around the die mounting area; and
a cap located in the cap receiving area with resilient contacts in locations corresponding to at least some contact pad locations on one of a die or a secondary circuit board affixed to a die to establish contact between the resilient contacts on the cap and the contact pad locations.

2. A die package, comprising:
a circuit board with a die mounting area;
a cap receiving area on the circuit board located above and at least partially around the die mounting area;
a cap located in the cap receiving area with resilient contacts in locations corresponding to at least some contact pad locations on one of a die or a secondary circuit board affixed to a die to establish contact between the resilient contacts on the cap and the contact pad locations; and
a die affixed in the die mounting area, and electrical connections extending between at least some of the contact pad locations on the die and the circuit board.

3. A die package, comprising:
a circuit board with a die mounting area;
a cap receiving area on the circuit board located above and at least partially around the die mounting area; and
a cap located in the cap receiving area with resilient contacts in locations corresponding to at least some contact pad locations on one of a die or a secondary circuit board affixed to a die to establish contact between the resilient contacts on the cap and the contact pad locations, the resilient contacts being formed in an array in a sheet of resilient conductive material, each of the contacts having an outwardly extending resilient contact arm, the contacts being bonded to an insulative sheet prior to singulation of at least some of the contacts from one another.

4. A die package, comprising:
a circuit board with a die mounting area;
a cap receiving area on the circuit board located above and at least partially around the die mounting area;
a cap located in the cap receiving area with resilient contacts in locations corresponding to at least some contact pad locations on one of a die or a secondary circuit board affixed to a die to establish contact between the resilient contacts on the cap and the contact pad locations; and
a first group of the contacts on the cap being located in complementary positions to contact pad locations on the die and the secondary circuit board, and a second group of the contacts on the cap being located in complementary positions to circuit board contacts positioned at least partially around the die mounting area.

5. A die package, comprising:
a circuit board with a die mounting area;
a cap receiving area on the circuit board located above and at least partially around the die mounting area; and
a cap located in the cap receiving area with resilient contacts in locations corresponding to at least some contact pad locations on one of a die or a secondary circuit board affixed to a die to establish contact between the resilient contacts on the cap and the contact pad locations, the cap further comprises a printed circuit board or a printed wiring board.

6. A die package, comprising:
a circuit board with a die mounting area;
a cap receiving area on the circuit board located above and at least partially around the die mounting area;
a cap located in the cap receiving area with resilient contacts in locations corresponding to at least some contact pad locations on one of a die or a secondary circuit board affixed to a die to establish contact between the resilient contacts on the cap and the contact pad locations; and
resilient contacts for data IO connections to the cap.

7. A die package, comprising:
a circuit board with a die mounting area;
a cap receiving area on the circuit board located above and at least partially around the die mounting area;
a cap located in the cap receiving area with resilient contacts in locations corresponding to at least some contact pad locations on one of a die or a secondary circuit board affixed to a die to establish contact between the resilient contacts on the cap and the contact pad locations, and the cap further comprising a heat sink or a ground plane.

8. A die package, comprising:
a circuit board with a die mounting area;
a cap receiving area on the circuit board located above and at least partially around the die mounting area; and
a cap located in the cap receiving area with resilient contacts in locations corresponding to at least some contact pad locations on one of a die or a secondary circuit board affixed to a die to establish contact between the resilient contacts on the cap and the contact pad locations, and the cap further comprising a power plane.

9. A die package, comprising:
a circuit board with a die mounting area;
a cap receiving area on the circuit board located above and at least partially around the die mounting area; and
a cap located in the cap receiving area with resilient contacts in locations corresponding to at least some contact pad locations on a secondary circuit board affixed to a die to establish contact between the resilient contacts on the cap and the contact pad locations, and the secondary printed circuit board is flip chip connected to the die.

10. A die package, comprising:
a circuit board with a die mounting area;
a cap receiving area on the circuit board located above and at least partially around the die mounting area;
a cap located in the cap receiving area with resilient contacts in locations corresponding to at least some contact pad locations on one of a die or a secondary circuit board affixed to a die to establish contact between the resilient contacts on the cap and the contact pad locations, the die further comprises a contact pad region located in a center area of the die for connection with one of the secondary circuit board or the resilient contacts on the cap, and the die further having at least one of power, ground and IO contact pad region located around at least a portion of a periphery that are connected to contacts located on the circuit board.

11. A die package, comprising:
a circuit board with a die mounting area;
a cap receiving area on the circuit board located above and at least partially around the die mounting area; and
a removable cap located in the cap receiving area with resilient contacts in locations corresponding to at least some contact pad locations on one of a die or a secondary circuit board affixed to a die to establish contact between the resilient contacts on the cap and the contact pad locations.

12. A die package, comprising:
a circuit board with a die mounting area;
a cap receiving area on the circuit board located above and at least partially around the die mounting area;
a cap located in the cap receiving area with resilient contacts in locations corresponding to at least some contact pad locations on one of a die or a secondary circuit board affixed to die to establish contact between the resilient contacts on the cap and the contact pad locations; and
the circuit board further comprises a recess located in the die mounting area, the cap receiving area being located at least one of in and above the recess.

13. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die; and
at least one of pads or resilient contacts on an upper surface of the first cap and the other of pads and spring contacts on lower surface of the second circuit board located in complementary positions.

14. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions; and
a die affixed in each of the die mounting areas of the first and second circuit boards, and electrical connections extending between at least some of the contact pad locations on each of the dice and a respective one of the first and second circuit boards.

15. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions;
the first and second caps each further comprising:
the resilient contacts formed in an array in a sheet of resilient conductive material, each of the contacts having an outwardly extending resilient contact arm, the contacts being bonded to the respective cap prior to singulation of at least some of the contacts.

16. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions; and
a first group of the contacts on the first cap being located in complementary positions to contact pad locations on the one of the die and the secondary circuit board of the first die package, and a second group of the contacts on the first cap being located in complementary positions to contacts on the first circuit board positioned at least partially around the die mounting area of the first die package.

17. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions; and
a first group of the contacts on the second cap being located in complementary positions to contact pad locations on the one of the die and the secondary circuit board of the second die package, and a second group of the contacts on the second cap being located in complementary positions to contacts on the second circuit board positioned at least partially around the die mounting area of the second die package.

18. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions; and
the first and second caps further comprise one of a printed circuit board and a printed wiring board.

19. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions; and
the resilient contacts are provided for data IO connections to at least one of the first and second caps.

20. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions; and
at least one of the first and second caps comprises at least one of a heat sink and a ground plane.

21. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions; and
at least one of the first and second caps further comprises a power plane.

22. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions; and
at least one of the die packages includes the secondary printed circuit board which is flip chip connected to the die.

23. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions; and
at least one of the dice further comprises a contact pad region located in a center area of the respective die for connection with one of the secondary circuit board or the resilient contacts on the cap, and the respective die further includes at least one of power, ground and IO contact pad region located around at least a portion of a periphery that are connected to contacts located on the respective one of the first and second circuit boards.

24. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions; and
the first die package being removably connected to the second die package.

25. An integrated multi-chip package, comprising:
a first die package having a circuit board a die mounting area, a cap receiving area on the circuit board located at least partially around the die mounting area, and a cap located in the cap receiving area with resilient contacts located on a lower surface thereof in locations corresponding to at least some contact pad locations on one of a die or a secondary circuit board affixed to a die;
a second die package having a second circuit board with a second die mounting area, a second cap receiving area on the second circuit board located at least partially around the second die mounting area, and a second cap located in the second cap receiving area with resilient contacts in locations corresponding to at least some contact pad locations of a second die or a second secondary circuit board affixed to a second die;
at least one of pads or resilient contacts on an upper surface of the first cap and the other of pads and spring contacts on lower surface of the second circuit board located in complementary positions; and
at least one of the first and second caps is removably connected to a respective one of the dice or the secondary circuit boards affixed to the respective dice and the respective one of the first and second circuit board.

26. A die package, comprising:
a circuit board with a die mounting area;
a cap receiving area on the circuit board located at least partially around the die mounting area;
a die with at least one of resilient contacts extending from contact pads on an upper surface thereof or a secondary circuit board affixed to the upper surface thereof with the secondary circuit board including at least one circuit in electrical communication with the contact pads on the die and the resilient contacts located on an upper surface of the secondary circuit board; and
a cap located over the die in the cap receiving area with at least one contact pad located on a lower surface thereof in a complementary position to the resilient contacts.

27. A die package, comprising:
a circuit board with a die mounting area;
a cap receiving area on the circuit board located at least partially around the die mounting area;
a die with a secondary circuit board affixed to the die, and resilient contacts extending from an upper surface of the secondary circuit board, the secondary circuit board including at least one circuit in electrical communication with contact pads on the die and the resilient contacts located on the upper surface of the secondary circuit board;
a cap located over the die in the cap receiving area with at least one contact pad located on a lower surface thereof in a complementary position to the resilient contacts; and
the resilient contacts comprising a plurality of contacts formed in an array in a sheet of resilient conductive material, each of the contacts having an outwardly extending resilient contact arm, the contacts being bonded to the secondary circuit board prior to singulation of at least some of the contacts from one another.

28. A die package, comprising:
a circuit board with a die mounting area;
a cap receiving area on the circuit board located at least partially around the die mounting area;
a die with at least one of resilient contacts extending from contact pads on an upper surface thereof or a secondary circuit board affixed to the upper surface thereof with the secondary circuit board including at least one circuit in electrical communication with the contact pads on the die and the resilient contacts located on an upper surface of the secondary circuit board; and
a cap located over the die in the cap receiving area with at least one contact pad located on a lower surface thereof in a complementary position to the resilient contacts, the cap further comprises one of a printed circuit board and a printed wiring board.

29. A die package, comprising:
a circuit board with a die mounting area;
a cap receiving area on the circuit board located at least partially around the die mounting area;
a die with at least one of resilient contacts extending from contact pads on an upper surface thereof or a secondary circuit board affixed to the upper surface thereof with the secondary circuit board including at least one circuit in electrical communication with the contact pads on the die and the resilient contacts located on an upper surface of the secondary circuit board;
a cap located over the die in the cap receiving area with at least one contact pad located on a lower surface thereof in a complementary position to the resilient contacts; and
resilient contacts provided for data IO connections to the cap.

30. A die package, comprising:
a circuit board with a die mounting area;
a cap receiving area on the circuit board located at least partially around the die mounting area;
a die with at least one of resilient contacts extending from contact pads on an upper surface thereof or a secondary circuit board affixed to the upper surface thereof with the secondary circuit board including at least one circuit in electrical communication with the contact pads on the die and the resilient contacts located on an upper surface of the secondary circuit board; and
a cap located over the die in the cap receiving area with at least one contact pad located on a lower surface thereof in a complementary position to the resilient contacts, the cap further comprising at least one of a heat sink and a ground plane.

31. A die package, comprising:
a circuit board with a die mounting area;
a cap receiving area on the circuit board located at least partially around the die mounting area;
a die with at least one of resilient contacts extending from contact pads on an upper surface thereof or a secondary circuit board affixed to the upper surface thereof with the secondary circuit board including at least one circuit in electrical communication with the contact pads on the die and the resilient contacts located on an upper surface of the secondary circuit board; and
a cap located over the die in the cap receiving area with at least one contact pad located on a lower surface thereof in a complementary position to the resilient contacts, the cap further comprising a power plane.

32. A die package, comprising:
a circuit board with a die mounting area;
a cap receiving area on the circuit board located at least partially around the die mounting area;
a die with a secondary circuit board flip chip bonded to the die, the secondary circuit board including resilient contacts extending from an upper surface thereof, the secondary circuit board including at least one circuit in electrical communication with the contact pads on the die and the resilient contacts located on the upper surface of the secondary circuit board; and
a cap located over the die in the cap receiving area with at least one contact pad located on a lower surface thereof in a complementary position to the resilient contacts.
